(19) United States
(12) Patent Application Publication
(10) Pub. No.: US 2009/0004819 A1
(43) Pub. Date: Jan. 1, 2009

(54) Method of Fabricating Flash Memory Device

(75) Inventors: Whee Won Cho, Cheongju-Si (KR); Eun Soo Kim, Incheon-Si (KR); Suk Joong Kim, Kyeongki-do (KR)

Correspondence Address: MARSHALL, GERSTEIN & BORUN LLP, 233 S. WACKER DRIVE, SUITE 6300, SEARS TOWER, CHICAGO, IL, 60606, US

(73) Assignee: HYNIX SEMICONDUCTOR INC., Icheon-Si (KR)

(21) Appl. No.: 11/963,906

(22) Filed: Dec. 24, 2007

(30) Foreign Application Priority Data
Jun. 28, 2007 (KR) 2007-64427

(51) Int. Cl. H01L 21/76

(52) U.S. Cl. 438/435; 257/E21.54

(57) ABSTRACT

In one aspect of the inventive method, a tunnel insulating film, a first conductive layer, and an isolation mask pattern are formed over a semiconductor substrate. The first conductive layer and the tunnel insulating film are patterned along the isolation mask pattern. A trench is formed in the semiconductor substrate. The trench is gap filled with a first insulating film. A polishing process is performed in order to expose the first conductive layer. A height of the first insulating film is lowered. The first conductive layer on the first insulating film is gap-filled with a second insulating film.

### CROSS-REFERENCE TO RELATED APPLICATION

The priority to Korean patent application number 10-2007-64427, filed on Jun. 28, 2007, the disclosure of which is incorporated by reference in its entirety, is claimed.

### BACKGROUND OF THE INVENTION

The invention relates to a method of fabricating a flash memory device and, more particularly, to a method of fabricating a flash memory device, wherein an isolation layer can be easily formed while preventing damage to a floating gate.

As semiconductor devices have become more highly-integrated, the sizes of and distances between elements of the semiconductor devices have decreased significantly. A flash memory device is described below as an example.

A memory cell included in the flash memory device is formed by sequentially laminating a tunnel insulating film, a floating gate, a dielectric layer, and a control gate over a semiconductor substrate. A NAND flash memory device includes a memory cell array in which data are stored. The memory cell array includes a plurality of strings. Each string includes a plurality of memory cells and select transistors. The plurality of memory cells are connected in series within the string and the select transistors are connected to both ends of the string.

The strings are isolated from each other by isolation layers. In order to form the isolation layers, a trench for dividing isolation regions is formed and then gap-filled with the isolation layer. In order to form the trench, an isolation mask pattern is formed over a conductive layer for a floating gate and an etch process is then performed along the isolation mask pattern, thus forming the trench. A nitride film is generally used as the isolation mask pattern. The nitride film can be easily formed since it easily reacts to the conductive layer formed in a polysilicon layer and has been used as an isolation mask pattern since it has a great etch selectivity with the conductive layer. However, when the nitride film is subsequently removed, phosphoric acid is typically used as a wet etchant. When the etch process for removing the isolation mask pattern is performed, a surface of the conductive layer for the floating gate may be damaged. Due to this, the electrical properties of a semiconductor device can be degraded.

### BRIEF SUMMARY OF THE INVENTION

The method of the invention can reduce surface damage to a floating gate at the time of an etch process by using an oxide film as an isolation mask film instead of a nitride film, and can also lower the aspect ratio of a trench and easily perform a gap-fill process by performing an isolation layer formation process with it being divided up.

In a method of fabricating a flash memory device according to one embodiment of the invention, a tunnel insulating film, a first conductive layer, and an isolation mask pattern are sequentially formed over a semiconductor substrate. The first conductive layer and the tunnel insulating film are patterned along the isolation mask pattern. A trench is formed in the semiconductor substrate. The trench is gap filled with a first insulating film. A polishing process is performed in order to expose the first conductive layer. A height of the first insulating film is lowered. The first conductive layer on the first insulating film is gap-filled with a second insulating film.

After the second insulating film is gap-filled, a height of the second insulating film is preferably lowered by performing an etch process, a dielectric layer is preferably formed along a surface of the second insulating film and the first conductive layer, and a second conductive layer is preferably formed on the dielectric layer.

Before the trench is gap filled with the first insulating film, a third insulating film is preferably further formed along a surface of the trench. At this time, the third insulating film is preferably formed from an oxide film having an etch selectivity different from that of the first insulating film. The isolation mask pattern is preferably formed from a High Density Plasma (HDP) oxide film.

In a preferred embodiment, the first insulating film is formed using a spin coating method or is formed from a flowable film such as a Spin on Glass (SOG) film, for example.

The polishing process is preferably performed using a Chemical Mechanical Polishing (CMP) process. The CMP process is preferably performed using a slurry having a higher etch selectivity with respect to the first insulating film than with respect to the first conductive layer. At this time, the slurry is preferably neutral or acidic.

An abrasive is preferably included in the slurry, and may comprise cerium dioxide (CeO₂), preferably in an amount of 1 wt % or less of the total amount of the slurry.

The height of the first insulating film is preferably lowered so that a top surface of the second insulating film is 1 angstrom to 500 angstroms lower than that of an active region of the semiconductor substrate. The second insulating film is preferably formed from an HDP film or a tetra ethyl ortho silicate (O₃-TEOS) film.

### BRIEF DESCRIPTION OF THE DRAWINGS

FIGS. 1A to 1G are sectional views illustrating a method of fabricating a flash memory device according to an embodiment of the invention.

### DESCRIPTION OF SPECIFIC EMBODIMENTS

A specific embodiment according to the invention is described below with reference to the accompanying drawings.

However, the invention is not limited to the disclosed embodiment, but may be implemented in various manners. The embodiment is provided to complete the disclosure of the invention and to allow those having ordinary skill in the art to understand the scope of the invention. The scope of the invention is defined by the claims.

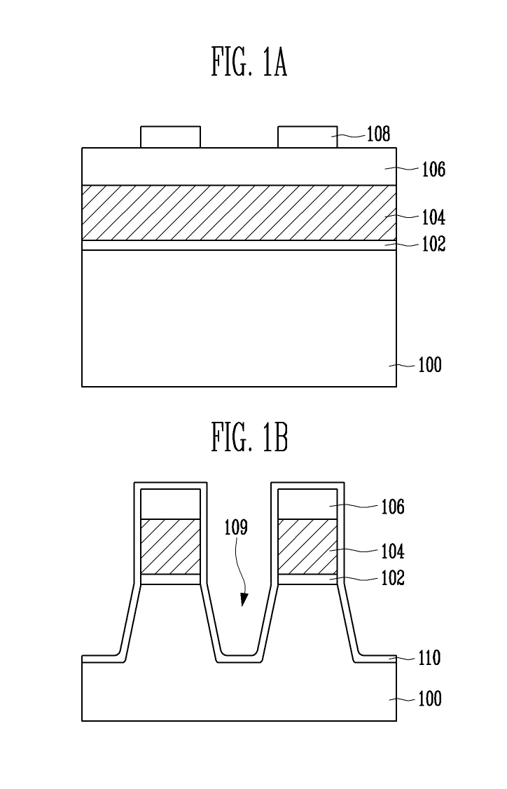

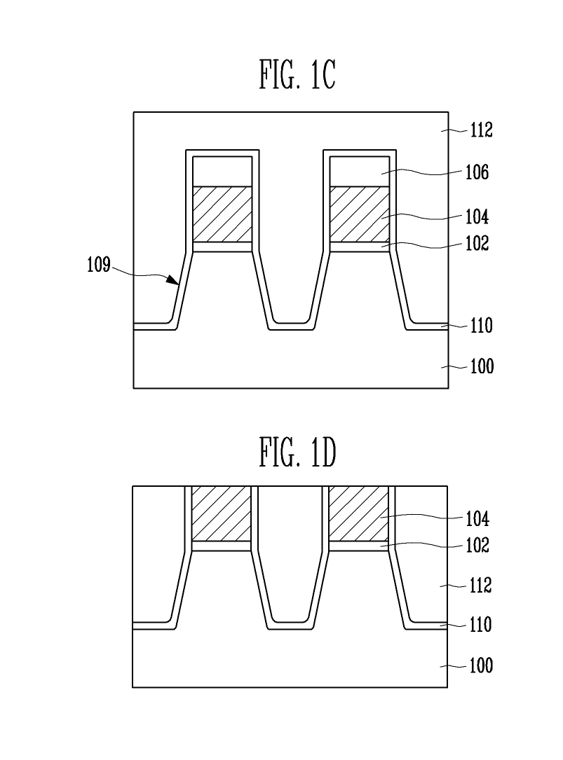

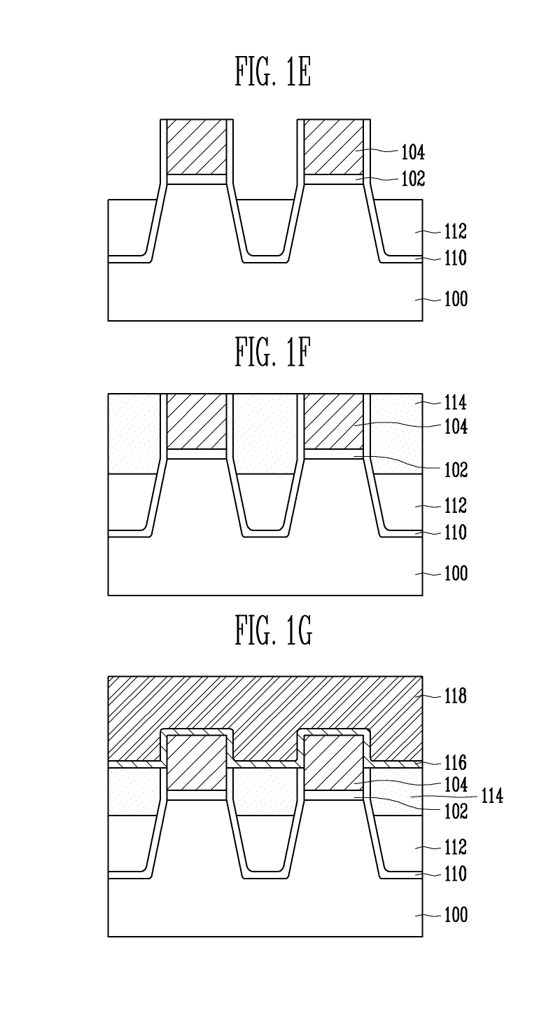

FIGS. 1A to 1G are sectional views illustrating a method of fabricating a flash memory device according to an embodiment of the invention.

Referring to FIG. 1A, a tunnel insulating film 102 and a first conductive layer 104 for a floating gate are sequentially laminated over a semiconductor substrate 100. The tunnel insulating film 102 is preferably formed from an oxide film and the first conductive layer 104 is preferably formed from a polysilicon layer.

An isolation mask film 106 may be formed on the first conductive layer 104. The isolation mask film 106 is preferably formed from an oxide film. In the prior art, the isolation mask film 106 was generally formed from a nitride film, but herein is preferably formed from an oxide film in order to reduce surface damage to the first conductive layer 104 for the floating gate when an etch process is subsequently performed. For example, the isolation mask film 106 may be formed from a High Density Plasma (HDP) oxide film having a dense film quality. A hard mask pattern 108 in which isolation regions are opened is formed on the isolation mask film 106.

Referring to FIG. 1B, the isolation mask film 106, the first conductive layer 104, and the tunnel insulating film 102 are sequentially patterned, preferably by performing an etch process along the hard mask pattern (refer to 108 of FIG. 1A). An exposed semiconductor substrate 100 is etched to form a trench 109.

The hard mask pattern (refer to 108 of FIG. 1A) is then removed. A first insulating film 110, preferably formed from an oxide film, is formed along the surfaces of the trench 109, the tunnel insulating film 102, the first conductive layer 104, and the isolation mask film 106, preferably by performing an oxidization process on the semiconductor substrate 100 including the trench 109.

Referring to FIG. 1C, a second insulating film 112 for an isolation layer is formed on the first insulating film 110. The second insulating film 112 is preferably formed to sufficiently cover the first insulating film 110 on the isolation mask film 106 so that the inside of the trench 109 is fully gap-filled.

The second insulating film 112 is preferably formed using a spin coating method or formed from a flowable film. For example, the second insulating film 112 may be formed from a flowable spin on glass (SOG) film, which can prevent the occurrence of void at the bottom of the trench 109.

Referring to FIG. 1D, a polishing process is performed in order to partially remove the second insulating film 112 and expose the first conductive layer 104. The polishing process is preferably performed using a chemical mechanical polishing (CMP) process. In particular, the CMP process is preferably performed using a slurry having a higher etch selectivity with respect to the second insulating film 112 than with respect to the first conductive layer 104. To this end, the CMP process is preferably performed using a slurry having neutral or acidic pH (for example, a pH in the range of 3 to no more than 8). A basic slurry has a high etch selectivity with respect to not only the oxide film, but also with respect to the conductive layer and, therefore, it may be difficult to stop the polishing process while exposing the first conductive layer 104 at the time of the CMP process. Therefore, in order to planarize the top surface of the first conductive layer 104, the second insulating film 112, and the first insulating film 110, the CMP process is preferably performed using a slurry of neutral or acidic pH as described above. More specifically, an abrasive is preferably included in the slurry, and preferably cerium dioxide (CeO₂), highly preferably in an amount of 1 wt % or less of the total amount of the slurry.

Consequently, the second insulating film 112 becomes an isolation layer, which forms a division between the first conductive layers 104. As described above, in the prior art, since the buffer layer and the nitride film were formed over the first conductive layer 104, the aspect ratio of the trench (refer to 109 of FIG. 1C) was high at the time of subsequent processes. In the invention, however, since the nitride film is not formed, the aspect ratio of the trench (refer to 109 of FIG. 1C) can be lowered at the time of subsequent processes.

Referring to FIG. 1E, the height of the second insulating film 112 is lowered, preferably by performing an etch process. The height the second insulating film 112 is lowered so that the trench (refer to 109 of FIG. 1C) is gap-filled with a film having a density greater than that of the second insulating film 112 formed from the flowable film.

In order to improve the insulating characteristic of the semiconductor device, the second insulating film 112 may have a height to the extent that gap-fill is not difficult in a subsequent process of forming the isolation layer. To this end, the height of the second insulating film 112 may be set to be the same as or lower than that of the tunnel insulating film 102. For example, the etch process may be performed such that a top surface of the second insulating film 112 is 1 angstrom to 500 angstroms lower than that of the active region of the semiconductor substrate 100.

Preferably, the etch process is performed using a higher etch selectivity with respect to the second insulating film 112 than with respect to the first insulating film 110. Accordingly, although the second insulating film 112 is etched to a height lower than that of the tunnel insulating film 102, the tunnel insulating film 102 is not damaged by the first insulating film 110.

Referring to FIG. 1F, a third insulating film 114 for an isolation layer is formed over the entire surface including the second insulating film 112. The third insulating film 114 is preferably formed from an HDP film or a tetra ethyl ortho silicate (O₃-TEOS) film.

At this time, since a nitride film is not used (unlike in the prior art) and the aspect ratio of the trench (refer to 109 of FIG. 1C) is reduced due to the formation of the second insulating film 112, the third insulating film 114 can be easily formed without generating voids. Furthermore, the aspect ratio can be further lowered since the isolation mask film 106 has been removed. A polishing process is then performed in order to expose a top surface of the first conductive layer 104. The polishing process is preferably performed using, for example, a CMP process.

Referring to FIG. 1G, the height of the third insulating film 114 is lowered by performing an etch process for controlling the Effective Field Oxide Height (EFH) of the third insulating film 114. At this time, the first insulating film 110 formed on the sidewalls of the first conductive layer 104 may also be removed. A dielectric layer 116 is formed along the surfaces of the third insulating film 114 for the isolation layer and the first conductive layer 104, and a second conductive layer 118 for a control gate is formed on the dielectric layer 116.

As described above, since the isolation layer formation process is performed over several times, the aspect ratio of the trench 109 can be reduced and therefore the occurrence of void in the isolation layers can be prevented. Further, since the oxide film is used as the isolation mask film instead of the nitride film, surface damage to the floating gate due to phosphoric acid typically used in the wet etch process of the nitride film can be prevented. Accordingly, the electrical properties of a flash memory device can be improved.

According to the invention, since the oxide film is used as the isolation mask film instead of the nitride film, surface damage to the floating gate when an etch process is performed can be reduced. Further, since an isolation layer formation process is performed over several times, the aspect ratio of the trench can be lowered. Accordingly, a gap-fill process can be performed conveniently, a thickness of the floating gate can be increased, and the coupling ratio can be increased.

What is claimed is:

1. A method of fabricating a flash memory device, the method comprising:
sequentially forming a tunnel insulating film, a first conductive layer, and an isolation mask pattern over a semiconductor substrate;
patterning the first conductive layer and the tunnel insulating film along the isolation mask pattern, and forming a trench in the semiconductor substrate;
gap-filling the trench with a first insulating film having a height;
performing a polishing process in order to expose the first conductive layer;
lowering the height of the first insulating film below to a height below that of the first conductive layer; and
gap-filling a second insulating film on the first insulating film.

2. The method of claim 1, further comprising, after gap-filling the second insulating film:
lowering a height of the second insulating film by performing an etch process;
forming a dielectric layer along a surface of the second insulating film and the first conductive layer; and
forming a second conductive layer on the dielectric layer.

3. The method of claim 1, further comprising forming a third insulating film along a surface of the trench before gap-filling the trench with the first insulating film.

4. The method of claim 3, comprising forming the third insulating film from an oxide film having an etch selectivity different from that of the first insulating film.

5. The method of claim 1, wherein the isolation mask pattern comprises a High Density Plasma (HDP) oxide film.

6. The method of claim 1, comprising forming the first insulating film using a spin coating method or from a flowable film.

7. The method of claim 6, comprising forming the first insulating film from flowable film formed from a Spin on Glass (SOG) film.

8. The method of claim 1, comprising performing the polishing process using a Chemical Mechanical Polishing (CMP) process.

9. The method of claim 8, comprising performing the CMP process using a slurry having a higher etch selectivity with respect to the first insulating film than with respect to the first conductive layer.

10. The method of claim 9, wherein the slurry is neutral or acidic.

11. The method of claim 10, wherein the slurry comprises a cerium dioxide (CeO₂) abrasive.

12. The method of claim 11, wherein the abrasive contains 1 wt % or less of the total amount of the slurry.

13. The method of claim 9, wherein the pH of the slurry is in the range of 3 to 8.

14. The method of claim 13, wherein the slurry comprises a cerium dioxide (CeO₂) abrasive.

15. The method of claim 14, wherein the abrasive contains 1 wt % or less of the total amount of the slurry.

16. The method of claim 1, comprising lowering the height of the first insulating film so that a top surface of the second insulating film is 1 angstrom to 500 angstroms lower than that of an active region of the semiconductor substrate.

17. The method of claim 1, wherein the second insulating film comprises a High Density Plasma (HDP) film or a tetra ethyl ortho silicate (O₃-TEOS) film.
